(19) United States
(12) Patent Application Publication
(10) Pub. No.: US 2008/0156519 A1
(43) Pub. Date: Jul. 3, 2008

(54) Printed circuit boardc structure

(75) Inventors: Chang-Liang Lin, Tainan City (TW); Chi-Lung Lee, Tainan City (TW); Hui-Yuan Liang, Tainan City (TW); Jiu-Yan Yan, Tainan City (TW)

Correspondence Address: BACON & THOMAS, PLLC, 625 SLATERS LANE, FOURTH FLOOR, ALEXANDRIA, VA, 22314, US

(73) Assignee: Bothhand Enterprise Inc., Tainan City (TW)

(21) Appl. No.: 12/005,298

(22) Filed: Dec. 27, 2007

(30) Foreign Application Priority Data
Dec. 29, 2006 (CN) 200620175409.8

(51) Int. Cl. H05K 1/03

(52) U.S. Cl. 174/252

(57) ABSTRACT

A printed circuit board structure including a carrier face on which a conductive layer is for connecting with electronic elements and a heat pipe texture arranged inside and along the printed circuit board structure. The printed circuit board is made of a material with good thermal conductivity, whereby the heat generated by the electronic elements can be quickly conducted to the heat pipe texture and quickly dissipated.

### BACKGROUND OF THE INVENTION

The present invention is related to an improved printed circuit board structure having a heat pipe texture. Electronic elements can be directly arranged on the printed circuit board. The heat generated by the electronic elements can be quickly conducted to the heat pipe texture and quickly dissipated.

FIG. 1 shows a conventional printed circuit board 30 on which a conductive layer 31 is disposed. An electronic element 20 such as a high-power light-emitting diode is laid on the printed circuit board 30 and connected with the conductive layer 31 via an SMD-type conductive pin 21.

The amount of the heat (accumulating heat) generated by the working electronic element 20 varies with the power thereof. The heat must be dissipated for maintaining normal operation of the electronic element 20. In order to enhance the heat-dissipating efficiency as a whole, not only the electronic element 20 has a heat-dissipating design itself, but also the printed circuit board 30 is equipped with a heat-dissipating module 40 for enhancing the heat-dissipating efficiency. As shown in FIG. 1, the heat-dissipating module 40 is arranged under the printed circuit board 30. The heat-dissipating module 40 is made of a material with high thermal conductivity, such as aluminum, copper, a complex material, a nanomaterial or the like. FIG. 2 shows another type of heat-dissipating module 40 which has a fin structure 41 for enlarging the heat-dissipating area of the printed circuit board 30.

According to the above arrangement, the heat is passively conducted outward. In the case that the electronic element 20 is a high-brightness light-emitting diode, the electronic element 20 will generate considerable heat. Under such circumstance, it is necessary to additionally arrange an active heat-dissipating device, for example, a fan, to increase heat-dissipating efficiency. As a result, more room will be occupied.

Taiwanese Patent Application No. 94124165 discloses a packaging structure for light-emitting diode with thermoelectric cell. During manufacturing, a thermoelectric cell is disposed between the light-emitting material and the printed circuit board. When the light-emitting diode is powered on, the heat is exchanged from the light-emitting material to the printed circuit board and dissipated from the heat-dissipating module positioned on the other face of the printed circuit board. This packaging structure is able to achieve better heat-dissipating effect. However, the manufacturing procedure of such structure is much more complicated than that of the conventional structure. In addition, each light-emitting diode necessitates such a thermoelectric cell. This increases the manufacturing cost. Therefore, it is tried by the applicant to redesign the structure of the printed circuit board for achieving thinner and lighter structure with better heat-dissipating efficiency at lower cost.

### SUMMARY OF THE INVENTION

It is therefore a primary object of the present invention to provide an improved printed circuit board structure which has simplified pattern and better heat-dissipating efficiency.

According to the above object, the printed circuit board structure of the present invention includes a carrier face on which a conductive layer is for connecting with electronic elements and a heat pipe texture arranged inside and along the printed circuit board structure. In working, the electronic elements will generate heat. The heat pipe texture is composed of multiple heat pipes parallelly arranged inside the printed circuit board. By means of the heat pipe texture, the heat generated by the electronic elements can be quickly dissipated. The printed circuit board is a thin flat board adapted to the parallel heat pipes and it is no more necessary to additionally dispose a heat-dissipating module on the printed circuit board. Therefore, the printed circuit board structure is simplified and thinned, while able to quickly dissipate the heat generated by the electronic elements.

The present invention can be best understood through the following description and accompanying drawings wherein:

### BRIEF DESCRIPTION OF THE DRAWINGS

FIG. 1 is a sectional view of a conventional printed circuit board;

FIG. 2 is a sectional view of another conventional printed circuit board;

FIG. 3 is a sectional view of a first embodiment of the printed circuit board of the present invention;

FIG. 4 is a perspective view of the first embodiment of the printed circuit board of the present invention;

FIG. 5 is a perspective view showing the application of the first embodiment of the printed circuit board of the present invention;

FIG. 6 is a perspective view of a second embodiment of the printed circuit board of the present invention; and

FIG. 7 is a perspective view of a third embodiment of the printed circuit board of the present invention.

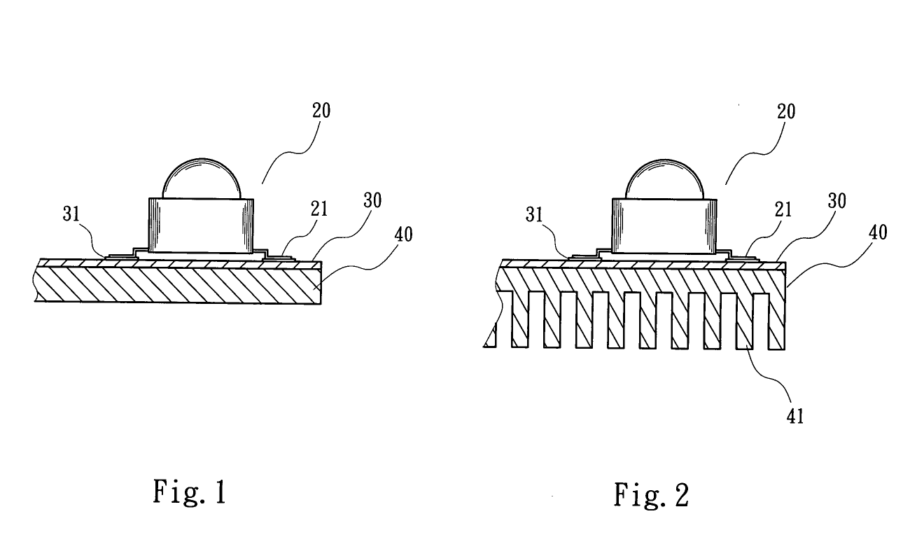

### DETAILED DESCRIPTION OF THE PREFERRED EMBODIMENTS

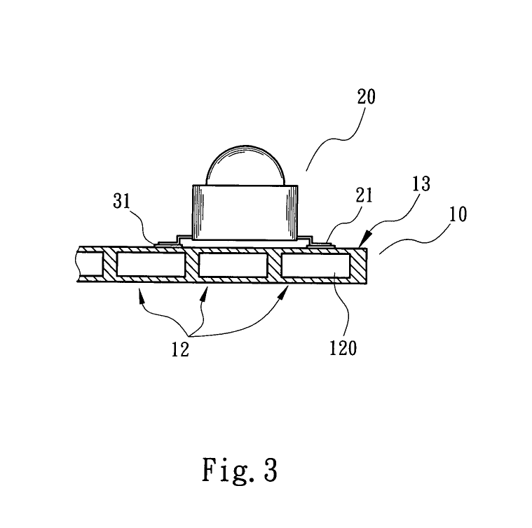

Please refer to FIG. 3. According to a preferred embodiment, the printed circuit board 10 of the present invention includes a carrier face 13 which is an insulating layer formed by means of anodization. A conductive layer 11 is laid on the carrier face 13 for connecting with the conductive section 21 of an electronic element 20. In this embodiment, the electronic element 20 is a light-emitting diode. The conductive layer 11 is a circuit structure directly laid on the carrier face 13. At least one heat pipe texture 12 is formed inside the printed circuit board 10. The heat pipe texture 12 includes one or more heat pipe 120 parallelly arranged inside and along the printed circuit board 10. In this embodiment, a phase-changeable material can be filled in the heat pipe, for example, an organic solvent such as methanol, ethanol, butyl alcohol, acetone or ammonia, pure water or a coolant. The internal accumulating heat generated by the working electronic element 20 can be quickly laterally dissipated through the parallel heat pipe texture 12. Even if a heat pipe 120 fails due to breakage and leakage, the remaining heat pipes 120 can still normal work to minimize the affection on the heat-dissipating efficiency. Moreover, the printed circuit board 10 is formed as a thin flat board adapted to the parallel heat pipe texture 12.

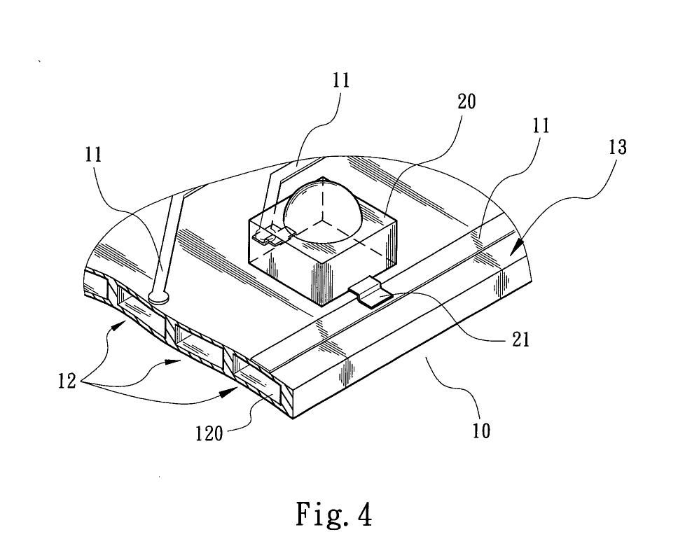

Referring to FIG. 4, an electronic element 20 is disposed on the printed circuit board 10. The electronic element 20 is positioned on the carrier face 13 adjacent to the conductive layer 11. When powered on to emit light, the heat generated inside the electronic element 20 is conducted through the conductive layer 11 and the carrier face 13 to the entire printed circuit board 10 which is made of thermal conductive material. At this time, the printed circuit board 10 quickly spreads the heat over the area around the electronic element 20. The heat is then actively exchanged between the printed circuit board and the phase-changeable coolant inside the heat pipes 120 parallelly arranged in the printed circuit board 10. Therefore, the heat can be quickly dissipated. The above structure is simple, while able to quickly dissipate the heat.

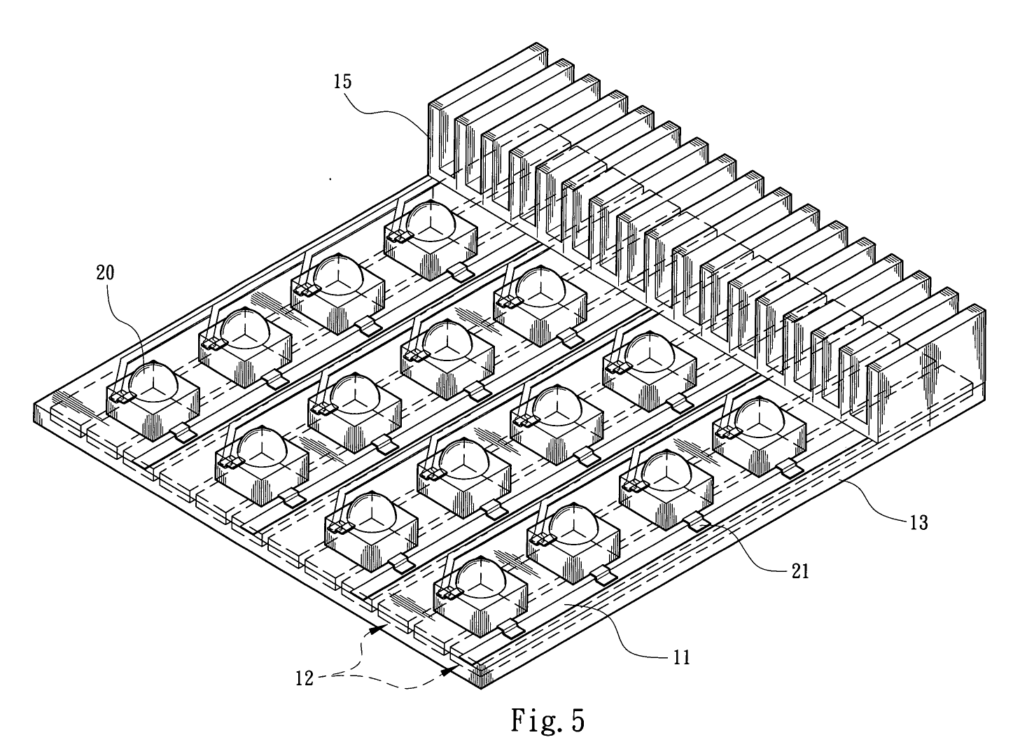

FIG. 5 shows an advertisement sign or television wall which necessitates many high-brightness light-emitting diodes 20. The printed circuit board 10 has multiple heat pipe textures 12. A conductive layer 11 is laid on the printed circuit board 10 as necessary. A great amount of electronic elements 20 are arranged on the carrier face 13 of the printed circuit board 10. The printed circuit board 10 is equipped with a suitable heat-dissipating structure and space, for example, a fin texture 15 formed on the printed circuit board 10. By means of the parallelly arranged heat pipe textures 12 and the cooperative fin texture 15, the heat generated by the electronic elements 20 can be quickly conducted by the printed circuit board 10 and dissipated. In practice, the printed circuit board 10 of the present invention is smaller than the conventional one so that the heat-dissipating space can be more freely designed. In short, the room occupied by the device as a whole can be minified.

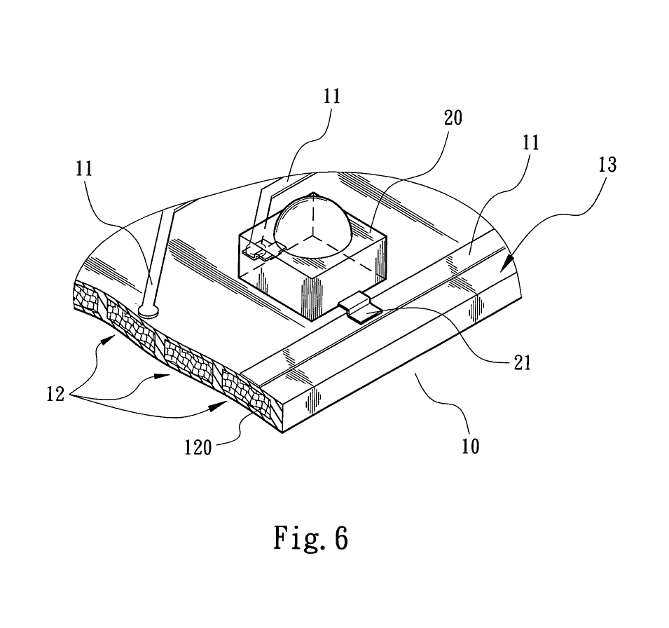

FIG. 6 shows another embodiment of the present invention, in which each heat pipe 120 of the heat pipe texture 12 has a heat-dissipating structure 14 for enlarging the area of the heat pipe 120 in contact with the heat source. In this embodiment, the heat-dissipating structure 14 is a metal network body composed of networks or filaments disposed in the heat pipe 120. Alternatively, the inner surface of the heat pipe 120 can be porously sintered or grooved. With the phase-changeable material filled in the heat pipe texture 12, such structure 14 has higher heat-dissipating efficiency. As shown in FIG. 6, the networked heat-dissipating structure 14 provides capillarity for the phase-changeable material in the heat pipe 120, whereby the flowing of the coolant material is speeded to expedite heat dissipation. In contrast to the conventional structure which employs thermoelectric cell for heat exchange, the present invention saves more energy, while achieving good heat-dissipating efficiency.

The printed circuit board 10 with the heat pipe texture 12 is applicable to different circuits, for example, a CPU socket of a main board or a display card. In another embodiment, a flexible printed circuit board (FPC) is laid on the carrier face 13 of the printed circuit board 10 by way of adhesion or any other suitable measure to form the conductive layer 11. With such structure, the heat generated in working can be also quickly dissipated through the heat pipe texture 12.

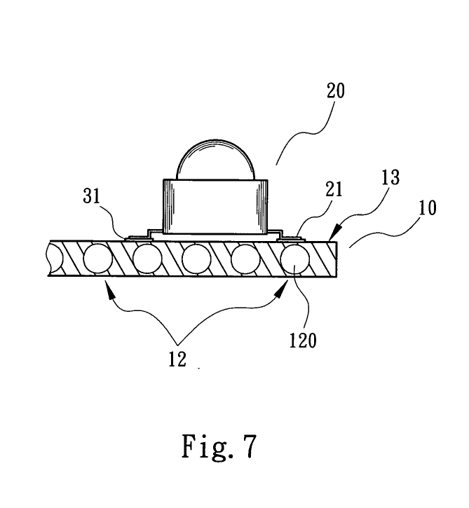

FIG. 7 shows another embodiment of the present invention, in which the heat pipe 120 of the heat pipe texture 12 has a circular cross-section, not rectangular cross-section, as shown in FIGS. 3 to 6. Alternatively, the heat pipe 120 can have an otherwise non-rectangular cross-section adapted to the structure of the printed circuit board 10 for enlarging heat-dissipating area.

In conclusion, the printed circuit board of the present invention is formed with the heat pipe texture and the electronic elements are directly laid on the carrier face of the printed circuit board. This structure is simple and able to achieve better heat-dissipating efficiency. Moreover, in contrast to the conventional printed circuit board, the present invention is applicable to those electronic elements with higher power, such as powerful transistor, high-speed operation chip, voltage transforming unit or the like. In addition, the space for the heat-dissipating module can be saved.

The above embodiments are only used to illustrate the present invention, not intended to limit the scope thereof. Many modifications of the above embodiments can be made without departing from the spirit of the present invention.

What is claimed is:

1. A printed circuit board structure comprising:
a carrier face on which a conductive layer is for connecting with electronic elements; and
a heat pipe texture composed of at least one heat pipe arranged inside and along the printed circuit board structure.

2. The printed circuit board structure as claimed in claim 1, wherein the heat pipe has a rectangular cross-section.

3. The printed circuit board structure as claimed in claim 1, wherein the heat pipe has a non-rectangular cross-section.

4. The printed circuit board structure as claimed in claim 1, wherein a heat-dissipating structure is disposed in the heat pipe.

5. The printed circuit board structure as claimed in claim 4, wherein the heat-dissipating structure is a metal network body composed of networks disposed in the heat pipe.

6. The printed circuit board structure as claimed in claim 4, wherein the heat-dissipating structure is a metal network body composed of filaments disposed in the heat pipe.

7. The printed circuit board structure as claimed in claim 4, wherein an inner surface of the heat pipe is porously sintered to form the heat-dissipating structure.

8. The printed circuit board structure as claimed in claim 4, wherein an inner surface of the heat pipe is grooved to form the heat-dissipating structure.

9. The printed circuit board structure as claimed in claim 1, wherein the carrier face is an insulating layer formed by means of anodization.

10. The printed circuit board structure as claimed in claim 4, wherein the carrier face is an insulating layer formed by means of anodization.

11. The printed circuit board structure as claimed in claim 1, wherein the heat pipe texture is composed of multiple heat pipes parallelly arranged inside the printed circuit board structure.

12. The printed circuit board structure as claimed in claim 4, wherein the heat pipe texture is composed of multiple heat pipes parallelly arranged inside the printed circuit board structure.

13. The printed circuit board structure as claimed in claim 1, wherein a material that can produce phase change is filled in the heat pipe.

14. The printed circuit board structure as claimed in claim 4, wherein a material that can produce phase change is filled in the heat pipe.

15. The printed circuit board structure as claimed in claim 9, wherein a material that can produce phase change is filled in the heat pipe.

16. The printed circuit board structure as claimed in claim 11, wherein a material that can produce phase change is filled in the heat pipe.

17. The printed circuit board structure as claimed in claim 13, wherein a material that can produce phase change is selected from pure water, coolant, organic solvent and a composition thereof.

18. The printed circuit board structure as claimed in claim 14, wherein a material that can produce phase change is selected from pure water, coolant, organic solvent and a composition thereof.

19. The printed circuit board structure as claimed in claim 15, wherein the phase-changeable material is selected from pure water, coolant, organic solvent and a composition thereof.

20. The printed circuit board structure as claimed in claim 16, wherein the phase-changeable material is selected from pure water, coolant, organic solvent and a composition thereof.

21. The printed circuit board structure as claimed in claim 1, wherein the conductive layer is a circuit directly disposed on the carrier face.

22. The printed circuit board structure as claimed in claim 4, wherein the conductive layer is a circuit directly disposed on the carrier face.

23. The printed circuit board structure as claimed in claim 9, wherein the conductive layer is a circuit directly disposed on the carrier face.

24. The printed circuit board structure as claimed in claim 11, wherein the conductive layer is a circuit directly disposed on the carrier face.

25. The printed circuit board structure as claimed in claim 13, wherein the conductive layer is a circuit directly disposed on the carrier face.

26. The printed circuit board structure as claimed in claim 17, wherein the conductive layer is a circuit directly disposed on the carrier face.

27. The printed circuit board structure as claimed in claim 1, wherein the conductive layer is a flexible printed circuit board (FPC) disposed on the carrier face.

28. The printed circuit board structure as claimed in claim 4, wherein the conductive layer is a flexible printed circuit board (FPC) disposed on the carrier face.

29. The printed circuit board structure as claimed in claim 9, wherein the conductive layer is a flexible printed circuit board (FPC) disposed on the carrier face.

30. The printed circuit board structure as claimed in claim 11, wherein the conductive layer is a flexible printed circuit board (FPC) disposed on the carrier face.

31. The printed circuit board structure as claimed in claim 13, wherein the conductive layer is a flexible printed circuit board (FPC) disposed on the carrier face.

32. The printed circuit board structure as claimed in claim 17, wherein the conductive layer is a flexible printed circuit board (FPC) disposed on the carrier face.

33. The printed circuit board structure as claimed in claim 1, wherein the electronic element is such an electronic element that in working state, the electronic element will generate heat.

34. The printed circuit board structure as claimed in claim 4, wherein the electronic element is such an electronic element that in working state, the electronic element will generate heat.

35. The printed circuit board structure as claimed in claim 11, wherein the electronic element is such an electronic element that in working state, the electronic element will generate heat.

36. The printed circuit board structure as claimed in claim 33, wherein the electronic element is a light-emitting diode.

37. The printed circuit board structure as claimed in claim 33, wherein the electronic element is a powerful transistor.

38. The printed circuit board structure as claimed in claim 33, wherein the electronic element is a high-speed operation chip.
